(19) United States
(12) Patent Application Publication
(10) Pub. No.: US 2016/0254612 A1
(43) Pub. Date: Sep. 1, 2016

(54) MODULE HOUSING FOR ELECTRONIC ASSEMBLY

(71) Applicant: CONTINENTAL AUTOMOTIVE GMBH, Hannover (DE)

(72) Inventors: SORIN ANDREI, TIMISOARA (RO); DETLEV BAGUNG, BERNHARDSWALD (DE); JÉROME CHASTANET, TOULOUSE (FR); GREGORY DREW, ZEITLARN (DE); BERND ROLLER, REGENSBURG (DE)

(21) Appl. No.: 14/910,336

(22) PCT Filed: Jul. 9, 2014
(86) PCT No.: PCT/EP2014/064764

§ 371 Date: May 9, 2016

(30) Foreign Application Priority Data
Aug. 5, 2013 (EP) 13464009.3

(51) Int. Cl. H01R 13/502; H05K 5/02; H01R 13/52; H05K 5/00

(52) U.S. Cl. CPC H01R 13/502; H05K 5/0004; H05K 5/0247; H01R 13/5202

(57) ABSTRACT

A module housing has a housing component for securing an electronic assembly and a plug connector for electrically connecting to the assembly. The plug connector has a main part with a plurality of receiving areas for electric plug contacts and a plug frame which surrounds the receiving areas. The module housing has a locking arrangement in order to mechanically secure the plug connector to the housing component, the locking arrangement has a locking element of the plug connector and a locking element of the housing component. The locking element of the plug connector has a hook element, and the locking element of the housing component has a corresponding recess for receiving the hook element.

The invention relates to a module housing. In particular, the invention relates to a module housing for receiving an electronic control device for use in a motor vehicle.

A module housing is set up for the purpose of receiving an electronic circuit which can include, in particular, a control instrument for controlling a system or sub-system on board a motor vehicle. A plug-in connector, which includes in the usual manner a plurality of plug-in contacts, is provided to produce an electric connection between the electronic circuit and further components. In order to protect the electronic circuit against dust and moisture, the plug-in connector can be sealed against the module housing by means of a hardening sealing compound. Such a housing is disclosed in DE 195 05 123.

During production of the module housing, production steps can be necessary where the plug-in connector is stressed mechanically with reference to the module housing. Sometimes, during said production steps the sealing compound has not yet been applied between the plug-in connector and the module housing or has not yet hardened. For example, after assembly of the module housing a leakage test can be effected where the plug-in connector is plugged into a corresponding receiving element. A final programming of the electronic circuit can also be effected where the plug-in contacts of the plug-in connector are connected to a programming device.

When plugging in and pulling out, mechanical forces can act on the plug-in connector which impair a correct alignment of the plug-in connector with reference to the module housing or to the electronic circuit. In particular, the plug-in connector can be tilted with reference to the module housing or the electronic circuit. As a result, a mechanical stress on electric connecting points can be generated between the plug-in connector and the electronic circuit which can result in failure of the control instrument at a later point. In addition, the seal of the module housing and the mountability of the assembly can be impaired.

EP 2034811 A2 discloses an electronic device with a bottom housing and a connector. The bottom housing has an open edge region, on the side wall of which fitting notches are arranged. The length-side ends of the connector housing are extended transversely to the plug-in direction by fitting projections which correspond to the fitting notches.

It is an object of the invention to provide a module housing by way of which improved mechanical fixing of the plug-in connector is achievable. The invention achieves said object by means of a module housing with the features of the independent claim. Preferred embodiments are provided by the sub-claims.

A module housing according to the invention comprises a housing component and a plug-in connector. The housing component is realized in particular for the fastening of an electronic assembly. The plug-in connector is realized in particular for the electric connection to the assembly. The plug-in connector comprises a plurality of receiving means for electric plug-in contacts and a plug-in frame which extends around the receiving means.

In an expedient manner, the plug-in connector has a basic body which includes the receiving means and comprises the plug-in frame. For example, the receiving means are realized in a base plate of the basic body, in particular they penetrate the base plate in a plug-in direction. The plug-in frame extends, for example, in opposition to the plug-in direction from one end which is connected to the base plate to an opening on a side of the plug-in frame remote from the base plate.

The module housing comprises a locking arrangement for the mechanical fastening of the plug-in connector on the housing part. The locking arrangement is provided in particular for the purpose of aligning the housing component and the plug-in connector with respect to one another.

The locking arrangement comprises a locking element of the plug-in connector and a locking element of the housing component. The locking element of the plug-in connector comprises a hook element. The locking element of the housing component comprises a corresponding recess for receiving the hook element. In this way, the locking elements of the plug-in connector and of the housing component are realized for the purpose of interacting with one another mechanically for locking the plug-in connector on the housing component. The concept ‘hook element’ includes, in this case, no limit to the particular shaping of the hook element, in particular no limit to a curved or angled form. The hook element is rather realized for the purpose of ‘hooking’ with the corresponding recess for locking the plug-in connector to the housing component, i.e. in particular forming a positive-locking connection.

In the case of one embodiment, the locking element of the plug-in connector extends parallel to an extension direction of the plug-in frame. The hook element can be arranged on one end of the locking element of the plug-in connector and extend at a right angle from the locking element.

In the case of one embodiment, the hook element is formed by a projection of an end portion of the basic body. The end portion preferably extends in the plug-in direction of the plug-in connector proceeding from the base plate. For example, the base plate forms a U-shape, which is open in particular in the plug-in direction, with two end portions that are situated opposite in a transverse direction. The projection preferably projects in a joining direction toward the locking element of the housing component. The joining direction, in this case, is in particular that direction in which the plug-in connector and the housing component are moved closer together and/or are put together when the module housing is assembled.

In the case of a further development, the shape of the recess corresponds to the shape of the projection. The recess and the projection are expediently arranged in such a manner that the projection engages in the recess, in a preferred manner the projection completely filling out the recess.

In a further development, the module housing additionally includes a housing closure in order to close the module housing together with the housing component and the plug-in connector on all sides. The housing closure, the plug-in connector and the housing component follow one after the other in the joining direction in particular in said order. By means of the housing closure, the module housing can be hermetically sealable, in particular by means of a sealing compound and the respective connecting points between the housing closure, the plug-in connector and the housing component.

In the case of one embodiment, the hook element and the corresponding recess are arranged on an end of the housing component or of the plug-in connector which faces the housing closure with reference to a joining direction and extend in particular in the joining direction up to a maximum of the middle of the housing component or of the plug-in connection.

The housing module according to the present disclosure allows for a fixing of the plug-in connector with reference to the housing component which can prevent the plug-in connector from tilting or pivoting in an extensive manner. Both the housing component and the plug-in connector can be easily producible, for example using the casting or injection molding method, without requiring an additional undercut. The improved centering of the plug-in connector with reference to the housing component can contribute to the fact that even in the case of mechanical stress, as can occur, for example, in the case of the plugging-in and pulling out operations of the plug-in connector, the tightness and the absence of stress on the elements, in particular on the plug-in connector, are maintained.

In a preferred embodiment, two locking elements are arranged on oppositely situated boundaries of the plug-in connector. For example, the basic body has two end portions which are arranged on ends of the basic plate which are situated opposite one another in the transverse direction. The transverse direction, in this case, is perpendicular to the plug-in direction and in particular also perpendicular to the joining direction. Each of the end portions preferably has a locking element which is included by the locking arrangement with in each case one hook element. The tilting of the plug-in connector with reference to the housing component can thus be prevented in an improved manner with reference to positive and negative forces. As an alternative to this or in addition to it, the risk of the plug-in connector being unintentionally rotated about an axis parallel to the joining direction is particularly small.

In one embodiment, the plug-in frame comprises a width which is greater than its height by a multiple. The width, in this case, is in particular the extension in the transverse direction and the height is the extension in the joining direction. In the case of a further development, the locking elements are arranged in the region of portions of the plug-in frame which extend along the height. As a result, it is possible to make use of a lever action which can ensure the plug-in connector is fixed particularly well with reference to the housing component. The plug-in connector can comprise an indentation, which extends into the plug-in connector in opposition to a joining direction, on a portion of the plug-in frame which extends along the width. The housing component then has in an expedient manner a corresponding locking element for engagement in said indentation. As a result, in particular deforming of the plug-in connector when plugging into or pulling out of a corresponding plug-in connector is able to be reduced, in particular in a middle region that is not directly fixed by the locking arrangement. Plugging in and pulling out operations, in particular during a production process, can thus not influence the correct positioning and the absence of stress on the plug-in connector with reference to components connected thereto.

In a further preferred embodiment, the plug-in connector is set up for the purpose of being moved closer to the housing component in the joining direction—that is in particular in the direction of the hook elements—and the housing closure is set up for the purpose of being moved closer to the housing component in the same direction and being connected to said housing component in order to lock the plug-in connector between the housing component and the housing closure.

As a result, the locking element of the plug-in connector can be prevented from slipping out of the corresponding recess in the housing component if the module is put under mechanical stress and thus impairs the fixing of the plug-in connector with reference to the housing component.

A suitable exemplary embodiment of the invention is now described in more detail with reference to the accompanying figures, in which:

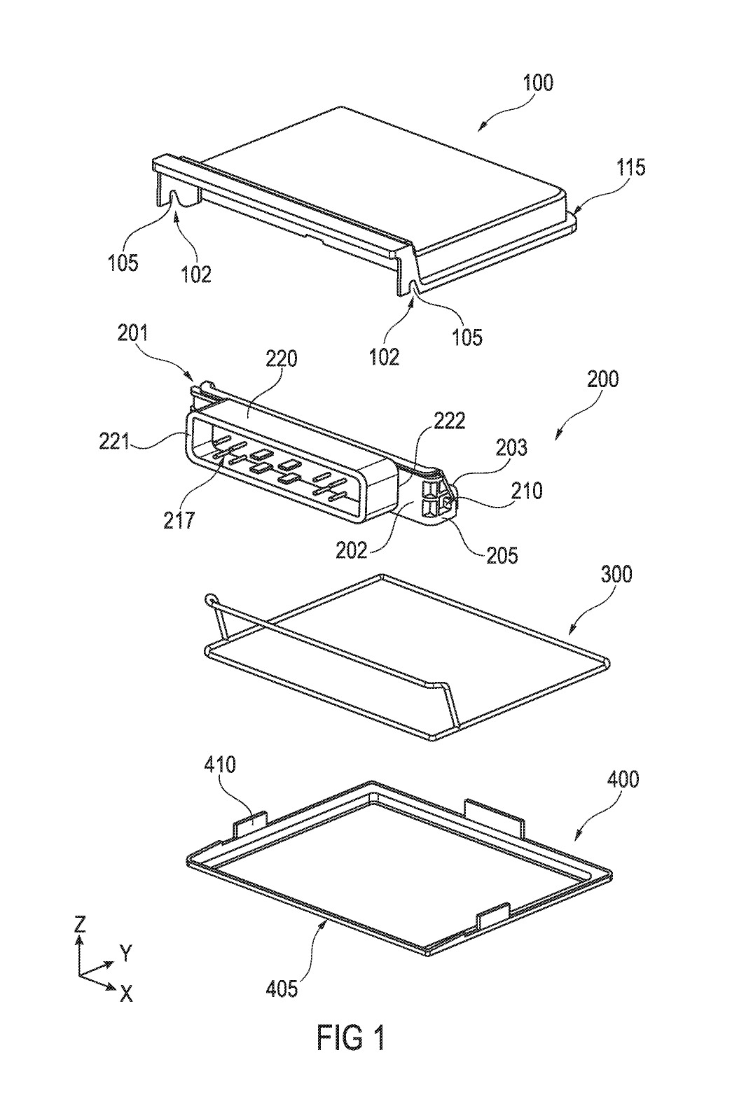

FIG. 1 shows an exploded representation of a module housing according to the suitable exemplary embodiment;

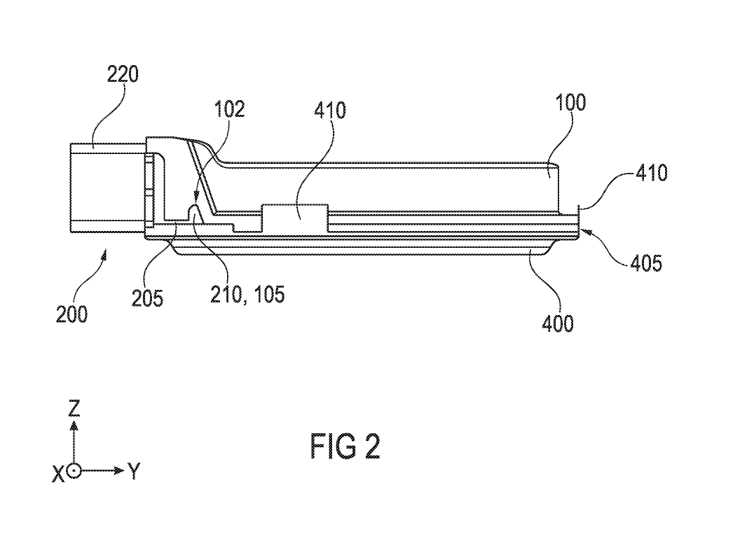

FIG. 2 shows a side view of the module housing from FIG. 1;

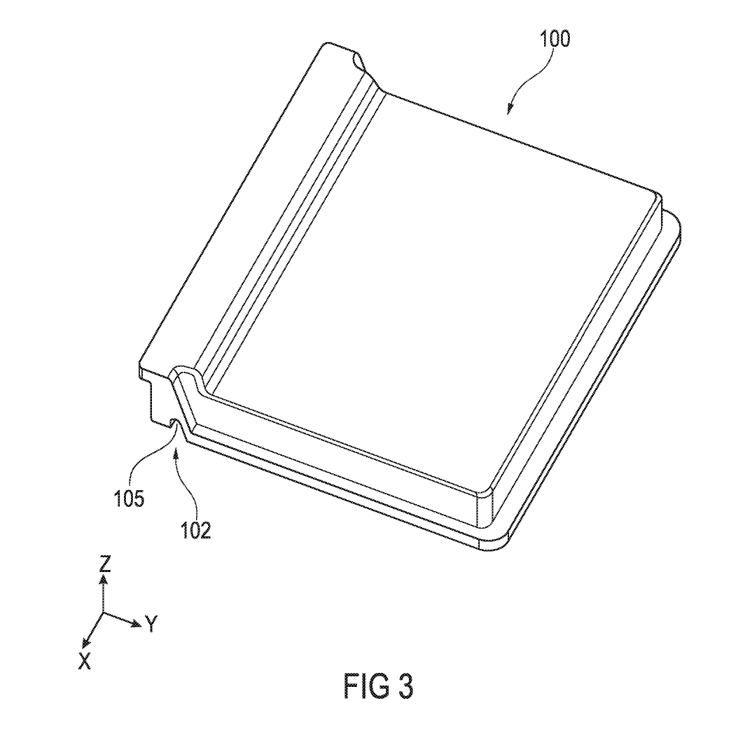

FIG. 3 shows a perspective view of the housing component of the module housing of FIG. 1;

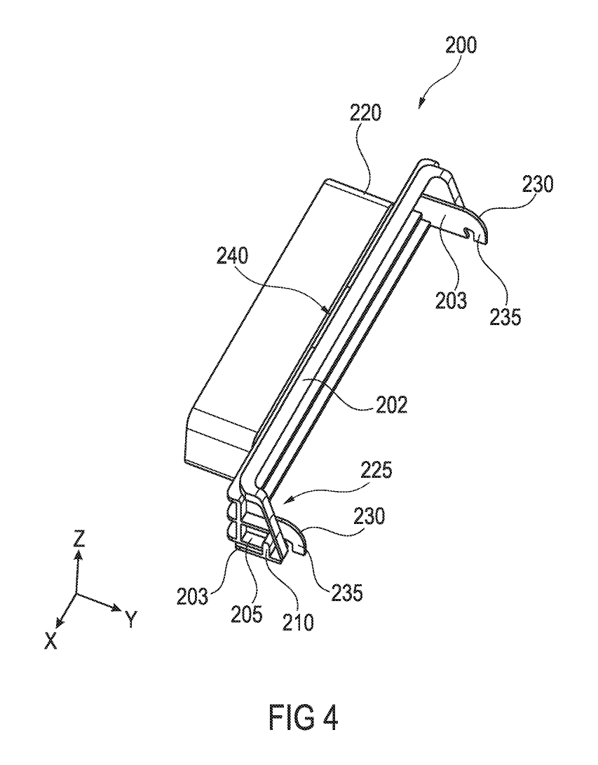

FIG. 4 shows a perspective view of the plug-in connector of the module housing of FIG. 1;

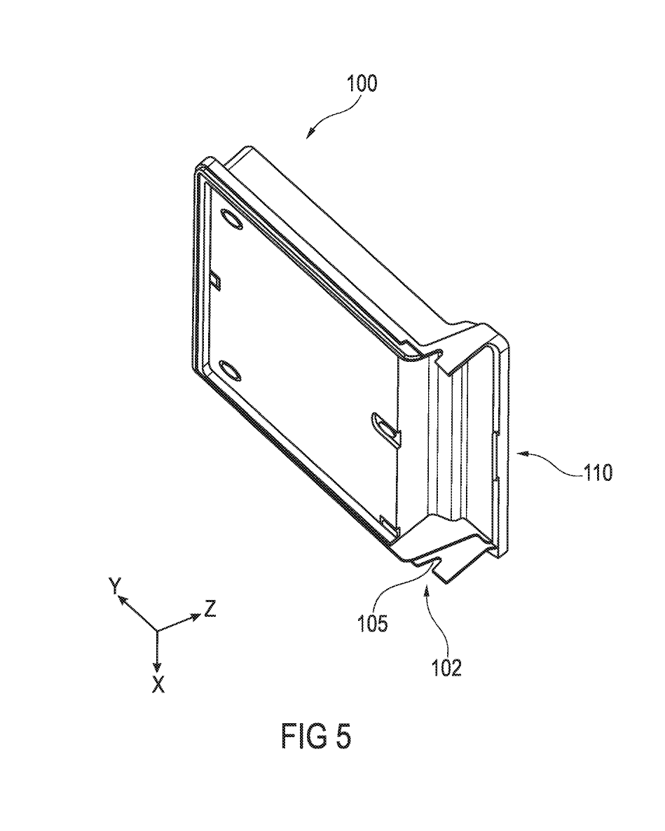

FIG. 5 shows a further perspective view of the housing component of the module housing of FIG. 1;

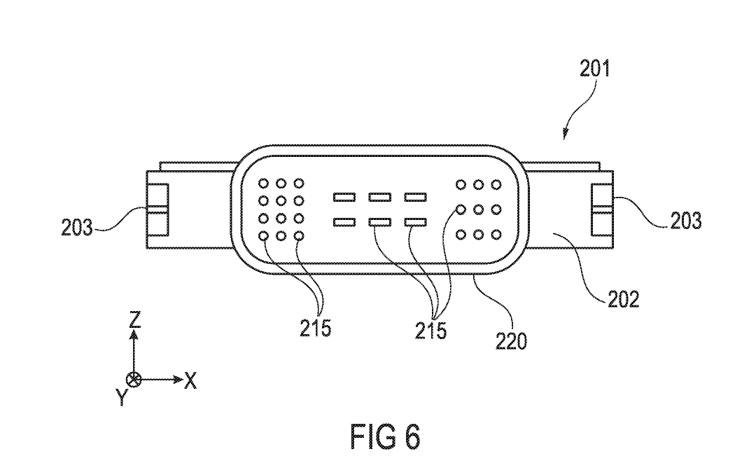

FIG. 6 shows a schematic side view of the plug-in connector of the module housing of FIG. 1.

FIG. 1 shows an exploded representation of a module housing. The module housing shown comprises a housing component 100, a plug-in connector 200, an optional sealing compound 300 and a housing closure 400. The housing component 100, the plug-in connector 200 and the housing closure 400, which can also be designated as a further housing component, surround an interior of the module housing.

FIG. 1 additionally provides a Cartesian coordinate system with an x, y and z direction. In said figure and in the following figures, use is made of said exemplary definition which is not to be understood as limiting.

The housing component 100 is producible in a preferred manner using casting or injection molding methods. For example, the housing component 100 consists of a metal. The housing component 100 is usually formed such that an electronic assembly, which can comprise in particular a circuit board, can be covered on at least one side by means of the housing component 100. In the representation in FIG. 1, the housing component 100 is set up for the purpose of covering the electronic assembly in four directions, namely in the positive z direction, in the position y direction as well as in the positive and negative x direction.

The plug-in connector 200 has a basic body 201 which, in a preferred manner, is also producible using the casting or injection molding method and is formed such that it can be moved into abutment or engagement with the housing component 100. The basic body 201 of the plug-in connector 200 is produced, for example, from a plastics material. The plug-in connector 200 can be mounted on the housing component 100 by being moved toward the housing component 100 in the positive z direction in the position shown.

The basic body 201 of the plug-in connector 200 comprises a plurality of receiving means 215 which are each provided for receiving an electric plug-in contact 217 of the plug-in connector 200. Each of the electric plug-in contacts 217 can be male or female or can include a further plug-in element such as a shield. In the preferred embodiment shown, the basic body comprises a plug-in frame 220 which is realized extending around the receiving means 215 or the plug-in contacts 217.

The plug-in frame 220 extends in the negative y direction in which the receiving means 215 or the plug-in contacts 217 received therein also extend. The receiving means 215 or the plug-in contacts 217 are covered by the plug-in frame 220 therefore in the positive and negative x direction and in the positive and negative z direction. For example, the receiving means 215 are included in a base plate 202 of the basic body 201 and the plug-in frame 220 extends in top view onto a main extension plane of the base plate 202 around the receiving means 215 or the plug-in contacts 217 (see FIG. 6). The plug-in frame 220 extends in a preferred manner from an end 222 which is connected to the base plate to an opening 201 which is remote from the base plate 202 such that it defines a plug-in direction which is in particular parallel to a normal on the main extension plane of the base plate. In the present case, the plug-in direction coincides with the (positive) y direction. The base plate 202 and the plug-in frame 220 are preferably portions of an integrally realized basic body 201.

The plug-in frame 220 is set up in particular for the purpose of engaging in a corresponding receiving means of a counter connector or a bushing which is connectable electrically and mechanically to the plug-in connector 200. The counter connector or the bushing is pluggable onto the plug-in frame 220 in particular in the plug-in direction. In one embodiment, the plug-in frame 220 includes one or several separating webs which extend along the z direction. Several plug-in frames 220 which are separate from one another can also be provided. The plug-in connector 200 extends over the entire width of the housing component 100. In particular, the base plate 202 of the basic body 201 of the plug-in connector 200 projects on both sides beyond the plug-in frame 220 in a transverse direction—which in the present case corresponds to the x direction. The basic body 201 comprises end portions 203 which connect to the base plate 202 in the transverse direction and extend away from the plug-in frame 220 at an angle—in particular perpendicular—to the transverse direction. In top view onto the plane formed by the transverse and plug-in direction, the end portions 203 form together with the base plate 202 a U-shape which is open in particular in the plug-in direction.

The housing closure 400 closes the module housing shown in the negative z direction. In one embodiment, the housing closure 400 is produced from a metal plate, for example as a result of embossing, pressing or deep-drawing. Top surfaces of the housing closure 400 which lie in the positive z direction are set up for the purpose of abutting against corresponding top surfaces in the negative z direction of the housing component 100 and of the plug-in connector 200. In this case, the sealing compound 300 can be provided between the housing closure 400 and the other components 100, 200.

In the embodiment shown, the housing closure 400 includes a circumferential edge 405 which extends in the positive z direction. The edge 405 is set up for the purpose of abutting against the housing component 100 in the x-y plane once the housing closure 400 has been mounted on said housing component. Bending lugs 410, which are formed on the housing closure 400, can be bent around the collar 115 of the housing component 100 in order to fix the housing closure 400 on the housing component 100.

In a different embodiment, the edge 405 can engage in a corresponding shoulder or a corresponding groove on the housing component 100. In a similar manner, the edge 405 can also abut against the plug-in connector 200 or engage in said plug-in connector. To this end, the plug-in connector 200 can also comprise a shoulder or a groove as well. The housing closure 400 can exert a clamping effect onto the housing component 100 and the plug-in connector 200 by means of the edge 405 such that the plug-in connector 200, once mounted on the components 100 and 400, is prevented by the edge 405 from being removed from the housing component 100 in the negative y direction. In other words, the edge 405 can encompass the housing component 100 and the plug-in connector 200 in such a manner that it defines a displacement of the plug-in connector 200 in opposition to the plug-in direction relative to the housing closure 400.

The housing closure 400, the plug-in connector 200 and the housing component 100 are put together in a joining direction.

In the present case, the joining direction corresponds to the (positive) z direction. For example, for mounting the module housing, the plug-in connector 200 is moved closer to the housing component 100 in the joining direction and fitted onto said housing component. The housing closure 400, for example, is then moved closer to the plug-in connector 200 and the housing component 100 in the joining direction and fitted onto them. The joining direction is preferably perpendicular to the plug-in direction and to the transverse direction. The plug-in direction and the transverse direction preferably span a main extension plane of the module housing on which the joining direction is perpendicular.

In the preferred embodiment shown, the sealing compound 300 is provided for the purpose of sealing the housing component 100, the plug-in connector 200 and the housing closure 400 in relation to one another. In a preferred manner, this is a hardening sealing compound which fastens the components 100, 200 and 400 mechanically to one another. An additional mechanical fixing, for example by screws, rivets or latching closures, is dispensed with in the case of a development.

In the region of a boundary in the negative y direction, the housing component 100 is formed to abut against or to engage with the plug-in connector 200. To this end, the boundaries in this region, in the positive and negative x direction, in each case carry a recess 105 which extends in the positive z direction such that open ends of the recess 105 point in the negative z direction. In the region of the boundaries in the positive and negative x direction, the plug-in connector 200 comprises in each case a locking element 205. The locking element 205 extends in the positive y direction and includes at its end a hook element 210 which is set up for the purpose of engaging in one of the recesses 105 of the housing component 100 in the positive z direction. The engagement is preferably effected in a positive locking manner such that no space remains between the plug-in connector 200 and the housing component 100. In a similar manner, the boundary of the plug-in connector 200 in the positive z direction abuts in as gap-free a manner as possible against a boundary of the housing component 100 in the negative z direction.

In other words, the module housing comprises a locking arrangement which is set up for the purpose of aligning the housing component 100 and the plug-in connector 200 with respect to one another. The locking arrangement comprises a locking element 102 of the housing component 100 and a corresponding locking element 205 of the plug-in connector 200. The locking element 102 of the housing component 100 is realized, for example, on an end portion, facing the plug-in connector 200, of a length-side side wall of the housing component 100—i.e. in particular extending from the plug-in connector 200 to an end of the housing component 100 which is located opposite the plug-in connector 200. The locking element 205 of the plug-in connector is realized, for example, on one of the end portions 203 of the basic body 201 of the plug-in connector 200. In the present case and in a preferred manner, the locking arrangement comprises two locking elements 102 of the plug-in connector 200 which are realized on the two end portions 203 of the basic body 201 which are situated opposite with reference to the transverse direction, and correspond to two locking elements 102 of the housing component 100 which are realized on length-side side walls of the housing component 100 which are situated opposite with reference to the transverse direction.

The locking element 205—or each of the locking elements 205—of the plug-in connector 200 comprises a hook element 210. The hook element 210 is, for example, a projection, in particular a lug, of the respective end portion 203 of the basic body 201 of the plug-in connector 200. The projection 210 projects in the joining direction toward the corresponding locking element 102 of the housing component 100.

The corresponding locking element 102 has a recess 105, the shape of which corresponds to the shape of the projection 210. In particular, the recess 105 is open in opposition to the joining direction. The recess 105 and the projection 210 are arranged in such a manner that with the module housing fitted together, the projection 210 engages in the recess 105. The projection 210 preferably completely fills out the recess 105.

FIG. 2 shows a side view of the module housing of FIG. 1. The x axis is directed toward the viewer. The representation shows the module housing of FIG. 1 in a fitted-together state, the sealing compound 300 not being visible.

It can be seen how the hook element 210 of the locking element 205 engages in the positive z direction in the recess 105 on the housing component 100.

The hook element 210 and the corresponding recess 105 are arranged on an end of the housing component 100 or of the plug-in connector 200 which faces the housing closure 400 with reference to the joining direction. In particular, they do not extend beyond the middle of the housing component 100 or of the plug-in connector 200 in the joining direction. In this way, the risk of the plug-in connector 200 unintentionally tipping about a rotational axis parallel to the transverse direction in the event of mechanical stress, e.g. when plugging in and pulling out the counter connector or the bushing, is particularly small. In particular, the plug-in connector 200 is prevented from tipping about a rotational axis which extends, for example, parallel to the x axis, by means of the abutment surfaces between the plug-in connector 200 and the housing component 100. In this case, the length of the locking element 205 can act as a support lever in the positive x direction.

It can also be seen how the edge 405 of the housing closure 400 clamps the plug-in connector 200 together with the housing component 100 in the x-y plane. The bending lugs 410 are not yet unbent in the representation of FIG. 2.

FIG. 3 shows a further view of the housing component 100 of the module housing of FIG. 1. In the perspective shown, one of the recesses 105 can be seen in particular clearer than in FIG. 1.

FIG. 4 shows a further view of the plug-in connector 200 of the module housing of FIG. 1. In this case, the perspective corresponds approximately to that of FIG. 3. It can be seen on the locking element 205 facing the viewer that the locking element 205 and the hook element 210 are fastened on a support structure 225 in the negative x direction such that in particular a portion of the locking element 205 extending in the positive y direction is protected against bending. The support structure 225 is formed integrally on the plug-in connector 200 and is a component part of the respective end portion 203 of the basic body 201. The support structure 225 comprises a wall which is located in the z-y plane and from which ribs extend in the positive x direction. Two of the ribs extend in the x-y plane and one further one extends perpendicular thereto in the x-z plane.

A holding element 230 which extends in the z-y plane is formed on the wall of the support structure 225 as an option. In this case, the holding element 230 is set up for the purpose of abutting against an inside surface of the housing component 100 in the positive x direction when the plug-in connector 200 is mounted on the housing component 100, such as, for example, shown in FIG. 2. In the preferred embodiment shown, the holding element 230 comprises a support 235 onto which the circuit board of the electronic assembly is able to be placed.

In the region of its boundary in the positive z direction—in other words on its end which faces the housing component 100 in the joining direction and is remote from the housing closure 400—the basic body 201 of the plug-in connector 200 additionally has an indentation 240. The indentation 240 is arranged, for example, in the middle of the plug-in frame 220 or of the base plate 202 with reference to the transverse direction. By means of a correspondingly formed engagement element 110 of the housing component 100, which is inserted in the negative z direction—i.e. in opposition to the joining direction—into the indentation 240, the plug-in connector 200 is held in particular in the positive and negative y direction as a result of mechanical interaction between the engagement element 100 and the indentation 240. As a result, forces which can be generated on the plug-in connector 200 when inserting or releasing a plug-in connection between the plug-in connector 200 and a corresponding connector, can be introduced into the housing component 100. This counters any bending or displacing of the plug-in connector 200 with reference to the housing component 100. The risk of the base plate 202 being bent out of the plane spanned by the transverse direction and the joining direction in a middle region between the locking elements 102, 105 which are located opposite with reference to the transverse direction, if it is stressed mechanically in or in opposition to the plug-in direction, is particularly low in this manner.

FIG. 5 shows a further perspective view of the housing component 100 of the module housing from FIG. 1. Here, it is possible to see the engagement element 110 on the housing component 100 which is set up for the purpose of engaging in the indentation 240 of the plug-in connector 200. In other embodiments, several engagement elements 110 can also be provided on the housing component 100 and several corresponding indentations 240 on the plug-in connector 200.

1-9. (canceled)

10. A module housing, comprising:
a housing component for fastening of an electronic assembly and having a locking element;
a plug-in connector for an electrical connection to the electronic assembly, said plug-in connector having electric plug-in contacts, a locking element, a basic body with a base plate and a plurality of receiving areas for said electric plug-in contacts, and a plug-in frame extending around said receiving areas;
said locking element of said housing component and said locking element of said plug-in connector together defining a locking configuration for mechanically fastening said plug-in connector on said housing component, said locking element of said plug-in connector and said locking element of said housing component are both realized for interacting mechanically with one another for locking said plug-in connector on said housing component; and
said locking element of said plug-in connector having a hook element and said locking element of said housing component having a corresponding recess formed therein for receiving said hook element, said hook element formed by a projection of an end portion of said basic body, said end portion extending in a plug-in direction of said plug-in connector proceeding from a base plate of said basic body containing said receiving areas, and said hook element is a projection projecting in a joining direction toward said locking element of said housing component.

11. The module housing according to claim 10, wherein:
said locking element of said plug-in connector extends parallel to an extension direction of said plug-in frame;
said hook element is disposed on an end of said locking element of said plug-in connector; and
said hook element extends at a right angle from said locking element of said plug-in connector.

12. The module housing according to claim 10, wherein a shape of said corresponding recess corresponds to a shape of said projection and said corresponding recess and said projection are disposed in such a manner that said projection engages in said corresponding recess.

13. The module housing according to claim 12, wherein said projection completely fills out said corresponding recess.

14. The module housing according to claim 10, wherein said locking element of said plug-in connector is one of two locking elements disposed on oppositely situated boundaries of said plug-in connector.

15. The module housing according to claim 10, wherein:
said plug-in frame has a width which is greater than its height by a multiple;
said plug-in connector has an indentation formed therein and extends into said plug-in connector in opposition to a joining direction of the module housing, on a portion of said plug-in frame which extends along said width; and
said housing component includes a corresponding engagement element for engagement in said indentation.

16. The module housing according to claim 10, further comprising a housing closure for closing the module housing together with said housing component and said plug-in connector on all sides.

17. The module housing according to claim 16, wherein said hook element and said corresponding recess are disposed on an end of said housing component or of said plug-in connector facing said housing closure with reference to a joining direction and extend in the joining direction up to a maximum of a middle of said housing component or of said plug-in connection.

18. The module housing according to claim 17, wherein:
said plug-in connector is set up for being moved closer to said housing component in a direction of said hook elements; and
said housing closure is set up for being moved closer to said housing component in a same direction and being connected to said housing component to lock said plug-in connector between said housing component and said housing closure.
